(19) United States
(12) Patent Application Publication
(10) Pub. No.: US 2026/0031138 A1
(43) Pub. Date: Jan. 29, 2026

(54) MULTI-LEVEL MEMORY CELL READ AND WRITEBACK SYSTEMS

(71) Applicant: Micron Technology, Inc., Boise, ID (US)

(72) Inventors: Daniele Vimercati, El Dorado Hills, CA (US); Shuai Xu, Santa Clara, CA (US); Veeresh Salimath, Folsom, CA (US)

(21) Appl. No.: 18/787,261

(22) Filed: Jul. 29, 2024

(51) Int. Cl. G11C 11/4096; G11C 11/4091

(52) U.S. Cl. CPC G11C 11/4096; G11C 11/4091

(57) ABSTRACT

A memory device includes an array of memory cells including at least first and second memory cells. Each of the cells can be configured to store a charge at two or more non-zero charge levels. A first local amplifier circuit can be configured to provide, at a first amplifier output node and during a first read phase, a first comparison result based on a first cell voltage signal of the first memory cell and a first voltage reference signal, and to provide, during a second read phase, a second comparison result based on the first cell voltage signal and a second voltage reference signal. First and second latch circuits can be configured to store information about the first and second comparison results, respectively. In an example, information from the first and second memory cells can be used together to provide a 3-bit codeword.

### BACKGROUND

Memory devices store information in various electronic devices such as computers, wireless communication devices, cameras, digital displays, and the like. Information is stored by programming memory cells within a memory device to various states. For example, binary memory cells can be programmed to one of two supported states, often denoted by a logic 1 or a logic 0. In some examples, a single memory cell can support more than two states, any one of which can be stored. To access the stored information, a component of the device can read, or sense, at least one stored state in the memory device. To store information, a component of the device can write, or program, the state in the memory device.

Memory devices include magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others. Memory devices can be volatile or non-volatile. Non-volatile memory, such as FeRAM, can be configured to store logical state information for extended time periods in the absence of an external power source. Volatile memory devices, such as DRAM, can lose stored logical state information when disconnected from an external power source. In some examples, an FeRAM-based device can have a storage density similar to that of a volatile memory device, however the FeRAM-based device can have non-volatile properties due to the use of a ferroelectric capacitor as a storage device.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates generally an example system that can include or use a memory device with local and global sense amplifiers.

FIG. 2 illustrates generally an example of a memory die and controller components.

FIG. 3 illustrates generally an example of a first chart showing examples of voltages or charges stored in a memory cell at respective different times.

FIG. 4 illustrates generally an example of a second chart showing examples of three different voltages or charges stored in a memory cell at respective different times.

FIG. 5 illustrates generally an example of a portion of a first memory device that can comprise a memory array and sense circuitry configured to read information from one or more memory cells.

FIG. 6 illustrates generally an example of a sense operation timing diagram.

FIG. 7 illustrates generally an example of a portion of a second memory device.

FIG. 8 illustrates generally an example of a local sense amplifier with a writeback shunt circuit.

FIG. 9 illustrates generally an example of a table that shows how signals stored using two multilevel memory cells can be decoded to provide more than 3 bits of information.

FIG. 10 illustrates generally an example of a first method for providing a 3-bit codeword based on information from a pair of multilevel memory cells.

FIG. 11 illustrates generally an example of a processing system that includes combinatory logic (i.e., circuitry) configured to provide one or more multi-bit words based on data stored in latch circuits of a memory device.

FIG. 12 illustrates generally an example of a memory cell usage optimization method that includes selecting a particular number of memory cells to use together to provide a multiple-bit word.

### DETAILED DESCRIPTION

A memory device can include a memory array to store data. The memory device can include a memory die. In some examples, the memory device can receive access commands (e.g., read, write, refresh, etc. commands) from a host device. In such examples, the memory device can use a sense component (e.g., sense amplifier). A sense component can be used to read a voltage signal or charge, indicative of a logical state, from a memory cell in the memory array. In some examples, the memory device includes multiple arrays or subarrays (e.g., tiles, subtiles) and each array or subarray includes a sense component. In various examples discussed herein, a local sense component can be provided to receive information from a first group of cells, and a global sense component can be provided to receive information from a larger second group of cells.

The present inventors have recognized, among other things, that a problem to be solved includes improving data storage efficiency in memory cells, such as DRAM cells. The problem can include increasing a bit density in memory cells without significantly increasing the physical area of the memory die. In other words, the problem can include storing more information in the same or smaller physical area than conventional devices use. In an example, a solution to these and other problems can include or use a memory cell that can store a signal at multiple levels, such as using multiple non-zero voltage levels.

In an example, the solution can include increasing the storage capacity of memory cells using a multilevel cell (MLC) configuration that allows for 1.5 bits per cell, or 3 bits from 2 cells. The solution includes a system that uses multiple reference voltage levels to help differentiate between various states, or levels of electrical charge, within the cells. By setting precise thresholds for these voltage levels, the solutions discussed herein can interpret different charge states as distinct information, effectively increasing the data that can be stored in a given area. In an example, the solution includes or uses both local and global sense amplifier configurations, with varying numbers of latches, to support the increased complexity of reading the multivalued voltage levels from one or more cells. Using combinatory logic to decode information from the memory cells, the solutions discussed herein improve bit density without using physically larger arrays, thus paving the way for more efficient and compact memory storage solutions.

In an example, a memory device uses subarrays (e.g., tiles, subtiles) that comprise single-transistor amplifiers to read memory cells on local digit lines. In an example, a local digit line can be directly coupled with the single-transistor amplifier(s) and a local sense amplifier. In an example, the local sense amplifier can include an operational amplifier or other differential amplifier circuit. The single-transistor amplifier can amplify a charge received from a corresponding memory cell and provide the amplified signal to the local sense amplifier. The local sense amplifier can perform a comparison of the amplified signal relative to one or more references and provide a comparison result to a global sense amplifier via a global digit line. In an example, the global sense amplifier can feed one or more latches to latch a logic state received from the global digit line.

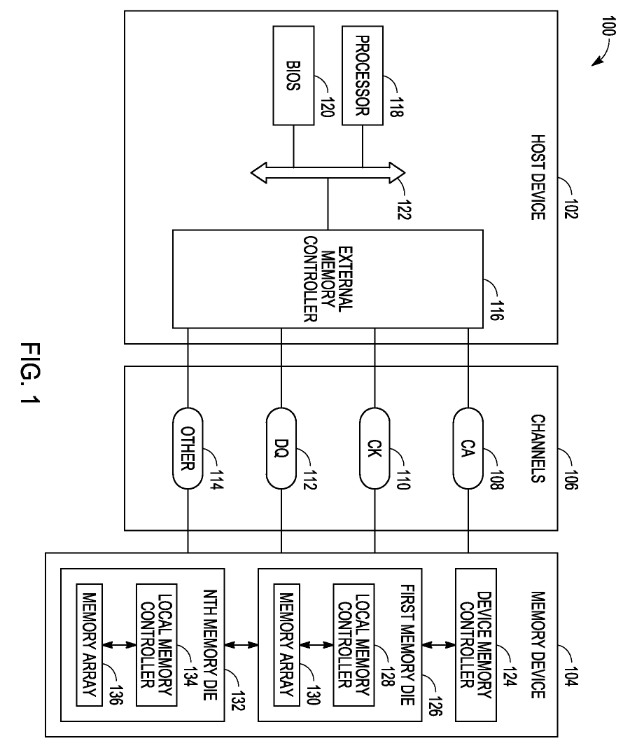

FIG. 1 illustrates generally an example system 100 that can include or use a memory device with local and global sense amplifiers. The example system 100 can include a host device 102, a memory device 104, and multiple channels 106 coupling that host device 102 to the memory device 104. In other examples, the example system 100 can include multiple memory devices 104. The example system 100 can include portions of an electronic device, such as a computing device, a mobile computing device, a wireless device, a graphics processing device, a vehicle, or other system or device.

The host device 102 can include an example of a processor or other circuitry within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 102 comprises hardware, firmware, software, and/or a combination thereof that implements the functions of an external memory controller 116.

The memory device 104 can include an independent device or a component that is operable to provide physical memory addresses/space that can be used or referenced by the example system 100. The memory device 104 can be configured to work with one or more different types of host devices. Signaling between the host device 102 and the memory device 104 can support one or more of modulation schemes to modulate the signals, various pin configurations for communicating the signals, various form factors for physical packaging of the host device 102 and memory device 104, clock signaling and synchronization between the host device 102 and the memory device 104, timing conventions, or other factors.

The memory device 104 can be configured to store data for components of the host device 102. In an example, the memory device 104 can include a secondary-type or dependent-type device to the host device 102, such as can be configured to respond to and execute commands provided by the host device 102 through the external memory controller 116. The commands can include one or more of a write command for a write operation, a read command for a read operation, a refresh command for a refresh operation, or other commands.

In an example, the host device 102 includes one or more of the external memory controller 116, a processor 118, a basic input/output system or BIOS 120, or other components such as one or more peripheral components or one or more input/output controllers. The components of the host device 102 can be coupled using a bus 122.

In an example, the processor 118 can be configured to provide control or other functionality for at least some portion of the example system 100 or at least some portion of the host device 102. The processor 118 can be a general-purpose processor, a digital signal processor (DSP), an application-specific integrated circuit (ASIC), a field-programmable gate array (FPGA), a tensor processing unit (TPU) (e.g., an AI accelerator application-specific integrated circuit (ASIC)) or other programmable logic device, discrete gate or transistor logic, discrete hardware component(s), or a combination of these components. In such examples, the processor 118 can include an example of a central processing unit (CPU), a graphics processing unit (GPU), a general purpose GPU (GPGPU), or an SoC, among other examples. In some examples, the external memory controller 116 can be implemented by or can comprise a portion of the processor 118.

The BIOS 120 can include a software component operated as firmware such as to initialize and run various hardware components of the example system 100 or the host device 102. The BIOS 120 can be configured to manage data flow between the processor 118 and various other components of the example system 100 or the host device 102. The BIOS 120 can include a program or software stored in one or more of read-only memory (ROM), flash memory, or other non-volatile memory.

The memory device 104 can include a device memory controller 124 and one or more memory dies to support a desired system capacity or a specified capacity for data storage. Each memory die (e.g., first memory die 126, Nth memory die 132, and one or more other memory dies) can include a respective local memory controller and array. For example, the first memory die 126 can comprise a first local memory controller 128 and a first memory array 130, and the Nth memory die 132 can comprise a second local memory controller 134 and a second memory array 136. In an example, a memory array (e.g., the first memory array 130 or the second memory array 136) can include multiple memory cells arranged in one or more grids, banks, tiles, sections, or other logical or physical areas, and each memory cell can be configured to store at least one bit of data. In some examples, one or more of the memory cells can be configured to store multiple bits of data, such as 1.5 bits per cell. A memory device 104 that includes two or more memory dies can be referred to as a multi-die memory or a multi-die package or a multi-chip memory or a multi-chip package.

The device memory controller 124 can include circuits, logic, or other components configured to control operation of the memory device 104. The device memory controller 124 can include the hardware, firmware, or other instructions that enable the memory device 104 to perform various operations, and the device memory controller 124 can be configured to receive, transmit, or execute commands, data, or control information related to the components of the memory device 104. The device memory controller 124 can be configured to communicate with one or more of the memory dies and the host device 102 (e.g., the external memory controller 116, the processor 118, etc.). Accordingly, the memory device 104 can use the device memory controller 124 to receive data or commands, or both data and commands, from the host device 102. In an example, the memory device 104 can receive a write command indicating that the memory device 104 is to store data for the host device 102 or a read command indicating that the memory device 104 is to provide data stored in one of its memory dies (e.g., the first memory die 126 or the Nth memory die 132) to the host device 102.

In an example, a local memory controller (e.g., the first local memory controller 128 or the second local memory controller 134) is local to a particular memory die and can include circuits, logic, or other components configured to control operation of a memory die. In some examples, a local memory controller can communicate (e.g., receive or transmit data or commands or both) with the device memory controller 124. In some examples, the host device 102 may not include a device memory controller, and a local memory controller or the external memory controller 116 performs various functions described herein. Accordingly, a local memory controller can be configured to communicate with one or more of the device memory controller 124, other local memory controllers, or the external memory controller 116, the processor 118, or a combination thereof. Examples of components that may be included in the device memory controller 124 or the local memory controllers 128, 134 can include receivers for receiving signals (e.g., from the external memory controller 116), transmitters for transmitting signals (e.g., to the external memory controller 116), combinatory logic such as decoders for decoding or demodulating received signals, encoders for encoding or modulating signals to be transmitted, or various other circuits or controllers configured to support operations of the memory device 104.

In an example, the external memory controller 116 can convert or translate communications between the components of the host device 102 and the memory device 104. The external memory controller 116 can include hardware, firmware, or software, or some combination thereof implemented by the processor 118 or other component of the example system 100. Although the example of FIG. 1 includes the external memory controller 116 illustrated external relative to the memory device 104, in some examples, the external memory controller 116, or devices configured to perform its functions described herein, can be implemented by one or more components of a memory device.

In an example, the example system 100 includes or uses combinatory logic configured to interpret the data stored in memory cells of the one or more memory arrays of the memory device 104. In an example, the combinatory logic is integrated with the device memory controller 124 to enable the memory device 104 to manage its own reading and writing processes internally, to ensure speed and efficiency. In another example, the combinatory logic is integrated with the external memory controller 116 at the host device 102.

The host device 102 can be configured to communicate with the memory device 104 using one or more channels 106. Each channel can comprise one or more signal paths or transmission mediums (e.g., conductors) between terminals associated with the components of the example system 100. In an example, a channel includes a first terminal including one or more pins or pads at the host device 102 and one or more corresponding pins or pads at the memory device 104. The channels 106 (and associated signal paths and terminals) can be dedicated to communicating one or more types of information. For example, the channels 106 can include one or more command and address or CA channels 108, one or more clock or CK channels 110, one or more data or DQ channels 112, and one or more other channels 114, or a combination thereof. In some examples, signaling can be communicated over the channels 106 using single data rate (SDR) signaling or double data rate (DDR) signaling.

The memory device 104 can include a plurality of subarrays in each memory array (e.g., each of the first memory array 130 and the second memory array 136). In such examples, each subarray, bank, etc., can include a local sense amplifier that reads a charge associated with a memory cell from a local digit line, compares the charge to one or more references, and outputs the comparison result to a global digit line coupled with a global sense amplifier. Using the local sense amplifier to provide a comparison result to the global sense amplifier can enhance the read margin and reduce an amount of area used by the sense amplifiers.

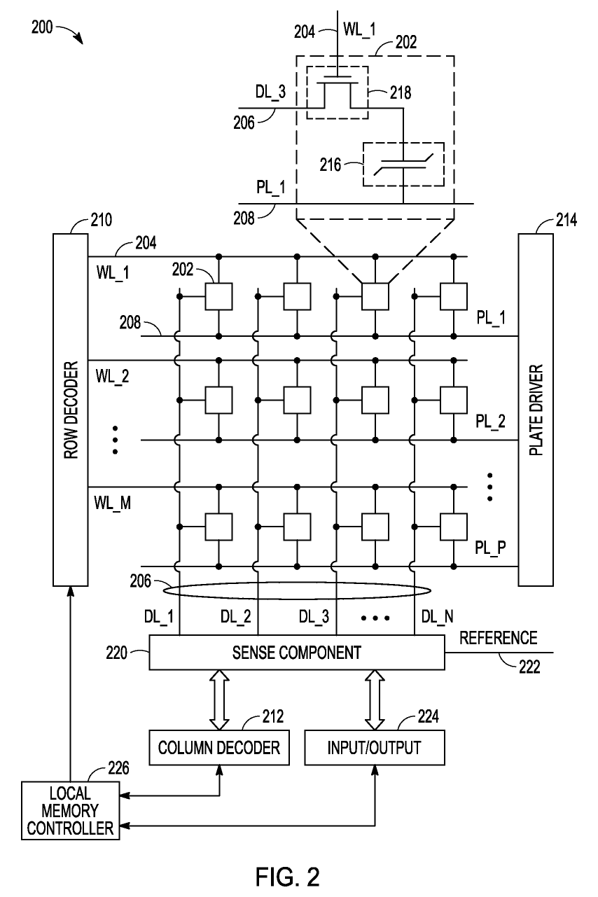

FIG. 2 illustrates generally an example of a memory die 200 and controller components in accordance with various examples discussed herein. The memory die 200 can include an example of the memory dies described with reference to FIG. 1, such as the first memory die 126 or the Nth memory die 132. In some examples, the memory die 200 can be referred to as a memory chip, a memory device, or an electronic memory apparatus, among other things. The memory die 200 can include one or more memory cells 202, and each of the memory cells 202 can be separately programmable to store different voltage signals that indicate one or more logic states. In an example, a particular memory cell 202 can store one bit of information at a time (e.g., a logic 0 or a logic 1). In some examples, a particular memory cell 202 (e.g., a multilevel memory cell) can store more than one bit of information at a time (e.g., a logic 00, logic 01, logic 10, a logic 11). In some examples, a particular memory cell 202 can store more than one bit but less than two bits of information at a time, as further discussed herein. In various examples, the memory cells 202 can be arranged in an array, such as the first memory array 130 or the second memory array 136 of the example system 100 of FIG. 1.

In an example, the memory cell 202 is configured to store a state (e.g., polarization state or dielectric charge) representative of the programmable states in a capacitor 216. In FeRAM architectures, the memory cell 202 includes a capacitor 216 that comprises a ferroelectric material that stores a charge and/or a polarization representative of the programmable state. The memory cell 202 can include a logic storage component, such as the capacitor 216, and a switching component 218, such as a transistor. A first node of the capacitor 216 can be coupled with the switching component 218 and a second node of the capacitor 216 can be coupled with a plate line 208. The switching component 218 can comprise a transistor or any other type of switch device that selectively establishes or de-establishes electronic communication between two components. The memory cells 202 can comprise DRAM memory cells or other types of memory cells.

The memory die 200 includes access lines, such as comprising word lines 204, digit lines 206, and plate lines 208. The access lines can be arranged in a pattern, such as a grid-like pattern. An access line includes a conductive line, or path, coupled with the memory cells 202 and is used to perform access operations on the memory cells 202. In some examples, the word lines 204 can be referred to as row lines. In some examples, the digit lines 206 can be referred to as column lines or bit lines. The various memory cells 202 are positioned at intersections of the word lines 204, the digit lines 206, and/or the plate lines 208.

Operations such as reading and writing can be performed on or using the memory cells 202 by activating or selecting particular access lines. For example, by biasing (e.g., providing a voltage to) a particular word line 204, digit line 206, and plate line 208, a particular cell of the memory cells 202 can be accessed at the corresponding access line intersection.

Accessing the memory cells 202 can be controlled using a row decoder 210, a column decoder 212, and a plate driver 214. For example, the row decoder 210 can receive a row address from a local memory controller 226 and, in response, activate a particular one of the word lines 204 based on the received row address. The column decoder 212 can receive a column address from the local memory controller 226 and, in response, active a particular one of the digit lines 206 based on the received column address. The plate driver 214 can receive a plate address from the local memory controller 226 and, in response, activate a particular one of the plate lines 208 based on the received plate address. In an example, the local memory controller 226 comprises an example of the first local memory controller 128, the second local memory controller 134, or the device memory controller 124 from the example system 100.

In an example, selecting or deselecting a particular memory cell 202 can be accomplished by activating or deactivating the switching component 218 corresponding to the particular memory cell 202. The corresponding capacitor 216 can be in electronic communication with the digit line 206 using the switching component 218. For example, the capacitor 216 can be isolated from the digit line 206 when the switching component 218 is deactivated, and the capacitor 216 can be coupled with the digit line 206 when the switching component 218 is activated.

A word line 204 can be a conductor in electronic communication with a memory cell 202 and used to perform access operations on the memory cell 202. In some architectures, the word line 204 can be in electronic communication with a gate of a switching component 218 of a memory cell 202 and can be configured to control the switching component 218. In some architectures, the word line 204 can be in electronic communication with a node of the capacitor 216 of the memory cell 202 and the memory cell 202 may not include a switching component.

A digit line 206 can be a conductor that connects the memory cells 202 with a sense component 220. In some examples, the memory cells 202 can be selectively coupled with the corresponding digit lines 206 during portions of an access operation. For example, the word line 204 and the switching component 218 of the memory cell 202 can be configured to selectively couple and/or isolate the capacitor 216 of the memory cell 202 and the digit line 206. In some architectures, the memory cell 202 can be in electronic communication (e.g., uninterrupted or constant communication) with the digit line 206.

A plate line 208 can be a conductor in electronic communication with a memory cell 202 that is used to perform access operations on the memory cell 202. The plate line 208 can be in electronic communication with a node of the capacitor 216. The plate line 208 can cooperate with the digit line 206 to bias the capacitor 216 during access operations.

In an example, the sense component 220 is configured to determine a state (e.g., a polarization state or a charge) stored on the capacitor 216 of the memory cell 202 and determine a logical state of the memory cell 202 based on the detected state. The sense component 220 can include one or more sense amplifiers (e.g., local and/or global sense amplifiers, as discussed elsewhere herein) to amplify the signal output of a memory cell 202. The sense component 220 can be configured to compare the signal received from a memory cell 202 (e.g., via the digit line 206) to a reference 222 (e.g., a reference voltage), and the reference 222 can be fixed or variable. The detected logic state of the memory cell 202 can be provided as an output of the sense component 220, such as to an input/output 224, and can indicate the detected logic state to another component of a memory device that includes the memory die 200.

In an example, the local memory controller 226 can control operation of memory cells 202 by controlling the various components of the memory die 200, such as the row decoder 210, the column decoder 212, the plate driver 214, and the sense component 220. The local memory controller 226 can be an example of the local memory controller of the example system 100 of FIG. 1. In some examples, one or more of the row decoder 210, the column decoder 212, the plate driver 214, and the sense component 220 can be co-located with the local memory controller 226. The local memory controller 226 can be configured to receive one or more of commands or data from one or more different memory controllers (e.g., the external memory controller 116 associated with the host device 102, or other controller associated with the memory die 200), translate the commands or the data (or both) into information that can be used by the memory die 200, perform one or more operations on the memory die 200, and communicate data from the memory die 200, such as to the host device 102 based on performing the one or more operations.

The local memory controller 226 can perform one or more access operations on one or more of the memory cells 202 of the memory die 200. Examples of access operations can include a write operation, a read operation, a refresh operation, a precharge operation, or an activate operation, among others. In some examples, access operations can be performed by or otherwise coordinated by the local memory controller 226 in response to various access commands (e.g., from the host device 102). The local memory controller 226 can optionally perform other access operations not discussed here or other operations related to the operating of the memory die 200 that may not be directly related to accessing the memory cells 202.

The local memory controller 226 can be operable to perform a write operation (e.g., a programming operation) on one or more memory cells 202 of the memory die 200. During a write operation, a target memory cell 202 of the memory die 200 can be programmed to store a desired logic state. The local memory controller 226 can identify the target memory cell 202 on which to perform the write operation. The local memory controller 226 can identify a target word line 204, a target digit line 206, and a target plate line 208 coupled with the target memory cell 202. The local memory controller 226 can activate the target word line 204, the target digit line 206, and the target plate line 208 (e.g., by applying a voltage to the corresponding word line 204, digit line 206, and plate line 208) to access the target memory cell 202. The local memory controller 226 can apply a specific signal (e.g., write pulse) to the digit line 206 during the write operation to store a specific state (e.g., charge) in the capacitor 216 of the target memory cell 202. The pulse used as part of the write operation can include one or more voltage levels over a duration.

The local memory controller 226 can perform a read operation (e.g., a sense operation) on one or more memory cells 202 of the memory die 200. During a read operation, the logic state stored in a target memory cell 202 of the memory die 200 can be determined. The local memory controller 226 can identify the target memory cell 202 on which to perform the read operation. The local memory controller 226 can identify the target word line 204, target digit line 206, and target plate line 208 coupled with the target memory cell 202. The local memory controller 226 can activate the target word line 204, target digit line 206, and target plate line 208 (e.g., by applying a voltage to the corresponding word line 204, digit line 206, and plate line 208) to access the target memory cell 202. The sense component 220 can sense charge information from the target memory cell 202 in response to the biasing on the access lines. The sense component 220 can be configured to amplify or transmit the sensed signal. The local memory controller 226 can activate the sense component 220 (e.g., latch the sense component 220) and compare the signal received from the target memory cell 202 to the reference 222. Based on the result of the comparison, the sense component 220 can determine a logic state (or other information) that is stored by the target memory cell 202.

In some examples, the local memory controller 226 can precharge an input stage and an output stage of a sense amplifier of the sense component 220 to a same voltage as at least one of a first side and a second side of a latch stage of the sense component 220 before enabling the sense component 220 for a read operation. In such examples, the read margin of the sense component 220 can be improved.

In an example, the memory cells 202 of the memory die 200 can be associated with a first group of memory cells 202 in the memory die 200 or the memory device 104. The sense component 220 can include a local sense amplifier that receives a charge associated with the memory cells 202 from the local digit lines 206. The local sense amplifier can compare the charge to one or more values of the reference 222 and output a comparison result to a global digit line (not illustrated in FIG. 2). The global digit line can be coupled with a second sense component associated with a different second group of memory cells in the same memory die 200 or a different die or memory device. In an example, the second sense component comprises a global sense amplifier configured to latch information read from multiple cells.

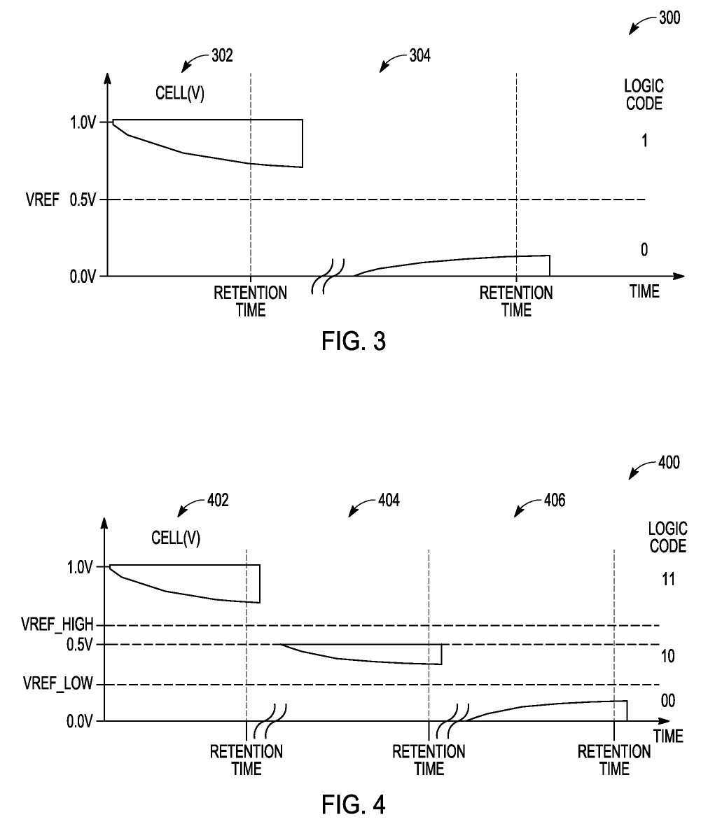

FIG. 3 illustrates generally an example of a first chart 300 showing examples of voltages or charges stored in a memory cell, such as a particular cell of the memory cells 202, at respective different times. In the first chart 300, the x-axis represents time and the y-axis represents the voltage stored in the cell. The first chart 300 illustrates generally a first voltage in the cell during a first time 302 and a second voltage in the cell during a subsequent second time 304.

In an example, a memory cell is considered to store a logical value “1” when the voltage in the cell is about 1 V, and the cell is considered to store a logical value “0” when the voltage in the cell is about 0 V. The specific voltage values discussed herein are examples only, and other values can similarly be used. Over time, due to inherent leakage phenomena, the voltage representing the stored value within the cell can drift; a cell initially at 0 V may experience an incremental voltage rise, whereas a cell initially at 1 V may exhibit a voltage decline. To counteract this leakage and preserve data integrity, the memory cell is periodically or intermittently refreshed, such as at a predetermined maximum retention time. In the first chart 300, the example of the first voltage is initially 1 V and decays to approximately 0.75 V at the retention time, and the second voltage is initially 0 V and increases to about 0.2 V at the retention time.

In an example, a voltage reference (VREF) can be provided. The voltage reference can provide a comparison point or threshold against which the cell voltage can be compared to determine whether the cell voltage represents a particular logical value, such as a logical 1 or 0. In the example of FIG. 3, the voltage reference can be 0.5 V. When the cell voltage is read from the cell, it can be compared against VREF, or the 0.5 V reference threshold, to determine whether the cell voltage represents a logical 1 or 0. For example, if the cell voltage is greater than VREF, then the cell is understood to store a logic code of 1. On the other hand, if the cell voltage is less than VREF, then the cell is understood to store a logic code of 0. The voltage comparison can be performed using a differential amplifier circuit, op-amp, or other comparator.

The present inventors have recognized, among other things, that more than two discrete voltage levels can be stored in a memory cell, and such levels can be identified, or distinguished from one another, using more than one voltage reference. FIG. 4 illustrates generally an example of a second chart 400 showing examples of three different voltages or charges stored in a memory cell at respective different times. In the second chart 400, the x-axis represents time and the y-axis represents the voltage stored in the cell. The second chart 400 illustrates generally a first voltage in the cell during a first time 402, a second voltage in the cell during a subsequent second time 404, and a third voltage in the cell during a further subsequent third time 406.

As similarly explained above in the example of FIG. 3, the voltages or charges stored in the cell can change over time due to charge leakage, and accordingly the memory cell can be refreshed to preserve data integrity. The refresh can be performed when a threshold time (e.g., the maximum retention time) is reached or refresh can be performed in response to a refresh command from a host or other controller.

In the second chart 400, the example of the first voltage is initially 1 V and decays to approximately 0.75 V at the retention time, the second voltage is initially 0.5 V and decays to about 0.4 V at the retention time, and the third voltage is initially 0 V and increases to about 0.2 V at the retention time.

The cell voltages or charges can be compared with multiple references or threshold voltages to determine which of multiple logical values is represented by the stored signal. For example, the thresholds can include a first reference voltage, or VREF_high, and a lower second reference voltage, or VREF_low. In an example, the memory cell is considered to store a logical value “11” when the voltage in the cell is greater than VREF_high, and the cell is considered to store a logical value “00” when the voltage in the cell is less than VREF_low. The memory cell can be considered to store a third logical value, such as “10” (or, similarly, “01”), when the voltage in the cell is greater than VREF_low and less than VREF_high.

In the example of FIG. 4, VREF_high can be about 0.6 V, and VREF_low can be about 0.25 V. When the cell voltage is read from the cell, it can be compared first with VREF_high to determine whether the cell voltage represents the logic code “11” or represents one of the two other logic codes (e.g., “10” or “00”). If the cell voltage does not represent the logic code “11,” then the same cell voltage can be compared with VREF_low to determine whether the cell voltage represents the logic code “10” or “00.” Alternatively, the cell voltage can be compared first with VREF_low to determine whether the cell voltage represents the logic code “00” or represents one of the two other logic codes (e.g., “10” or “11”). If the cell voltage does not represent the logic code “00,” then the same cell voltage can be compared with VREF_high to determine whether the cell voltage represents the logic code “10” or “11.”

In the example of FIG. 4, when the cell voltage is read from the cell during the first time 402, it can be compared against VREF_high to determine the cell voltage represents a logic code “11.” When the cell voltage is read from the cell during the third time 406, it can be compared against VREF_low to determine the cell voltage represents a logic code “00.” When the cell voltage is read from the cell during the second time 404, it can be compared first against one of VREF_high and VREF_low, and then against the other one of VREF_high and VREF_low, to determine the cell voltage represents a logic code “10.”

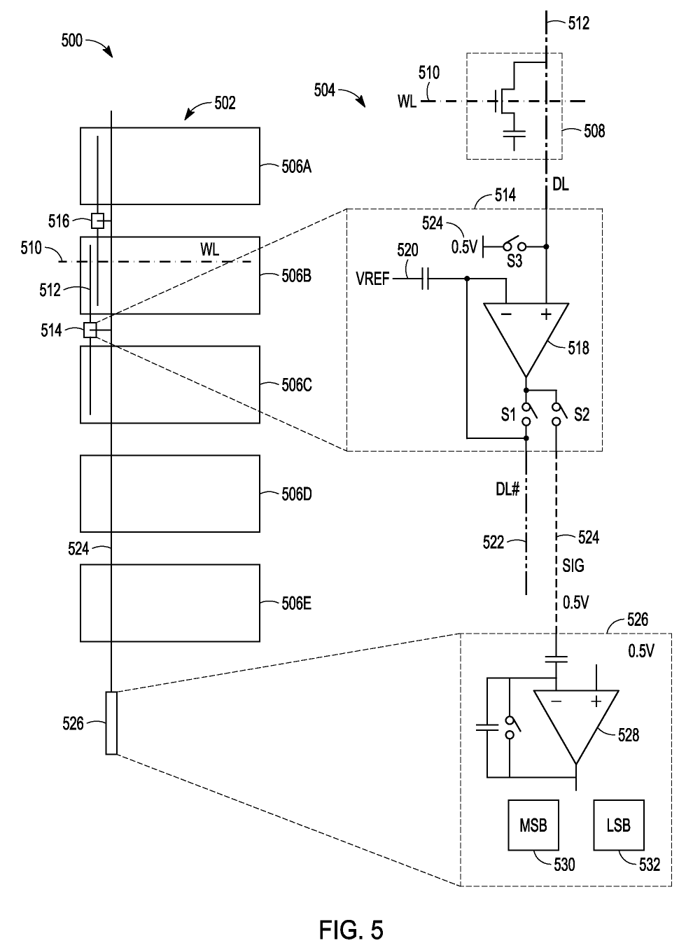

FIG. 5 illustrates generally an example of a portion of a first memory device 500 that can comprise a memory array 502 and sense circuitry 504 configured to read information from one or more memory cells of the memory array 502. In an example, the sense circuitry 504 is configured to read information from a multilevel memory cell of the memory array 502. The multilevel memory cell can be configured to store at least three levels of charge, and least two of the levels can be non-zero levels of charge.

In an example, the memory array 502 comprises a portion of the first memory array 130, the second memory array 136, or one or more other arrays of the memory device 104. The memory array 502 as illustrated includes multiple subarrays of memory cells, including a first cell array 506a through a Nth cell array 506e. In an example, the memory array 502 comprises a DRAM bank, or a half bank, or other portion of a bank of a DRAM memory device. Other types of volatile or non-volatile memory can similarly be used.

Various cells of the memory array 502 can be accessed. For example, in DRAM, memory cells are accessed via a grid-like structure of word lines and digit lines (also known as bit lines). When a specific memory cell, or first target memory cell 508 of a particular subarray, is to be accessed, the corresponding word line is activated, which connects all the cells along that line to their respective digit lines. The digit line associated with the target cell then senses or modifies the charge in the cell, allowing for the reading or writing of data. This selective activation of word lines and digit lines enables the precise addressing of individual memory cells within the memory array 502.

In the example of FIG. 5, the first target memory cell 508 in the second cell array 506b is accessed via a first word line 510, and stored charge information is made available from the first target memory cell 508 at a first digit line 512. The charge information is read and stored using the sense circuitry 504.

The sense circuitry 504 can include, among other things, a first local sense amplifier 514 and a global sense amplifier 526. The first local sense amplifier 514 can include a first amplifier circuit 518 with multiple inputs (e.g., inverting and non-inverting inputs). In an example, a non-inverting input of the first amplifier circuit 518 can be coupled to the first digit line 512 to receive the charge information from the first target memory cell 508 when the cell is activated. An inverting input of the first amplifier circuit 518 can be coupled to a voltage reference source that provides a constant or time-varying first local reference signal 520 (VREF). In an example, the inverting input is coupled to VREF via an in-line capacitor, and the inverting input can be selectively coupled to an output of the first amplifier circuit 518 using a first switch S1. In an example, the inverting input is coupled to a first digit line bar 522 or complement digit line. The first digit line bar 522 provides a matching capacitance, or capacitive load, that can be used to help read information from the multilevel first target memory cell 508, as further discussed below.

In an example, the first local sense amplifier 514 can include, or can be coupled to, a bias circuit 534. The bias circuit 534 can be configured to selectively provide a bias voltage signal to an input of the first amplifier circuit 518, such as to pre-charge the input or the first digit line 512. In an example, the bias circuit 534 includes a third switch S3 that can control whether the bias voltage signal is applied to the amplifier input.

In an example, an output of the first amplifier circuit 518 is coupled to the first switch S1 and a second switch S2, which can operate such that only one of the first switch S1 and the second switch S2 is closed and conducting at any given time. In some examples, discussed below, the first switch S1 and the second switch S2 can be open during a writeback operation.

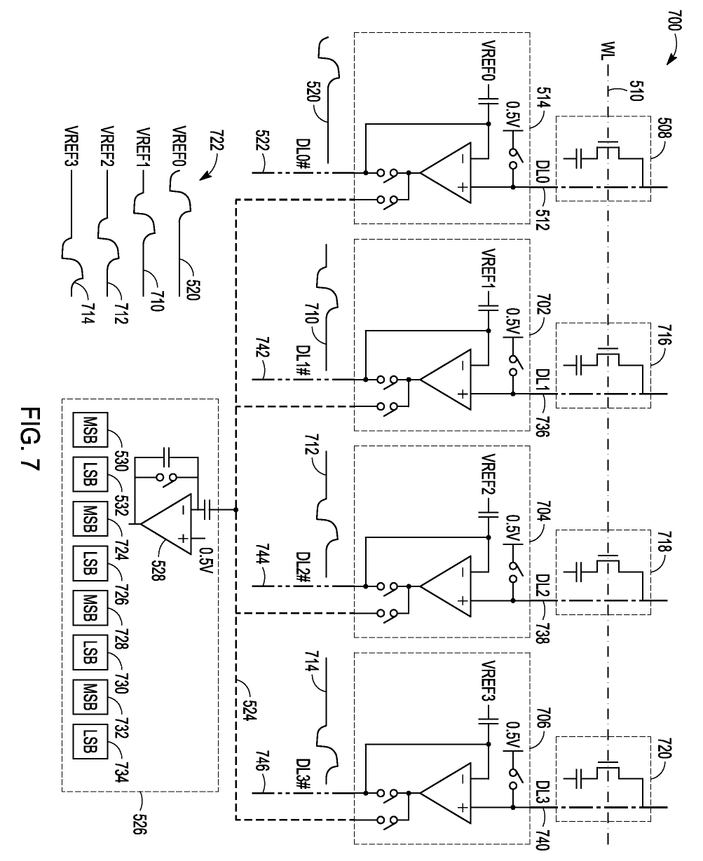

The second switch S2 selectively couples the output of the first amplifier circuit 518 to the global sense amplifier 526 via a signal line 524. The signal line 524 can be relatively long, optionally extending over one or more portions of the memory array 502, such as to receive information from a memory bank or a portion of a bank. The signal line 524 can be configured to receive information from multiple different local sense amplifiers, as further illustrated in the example of FIG. 7. That is, the signal line 524 can be configured to receive information, in a multiplexed manner, from multiple respective memory cells.

In an example, the global sense amplifier 526 is configured to receive an analog signal from the first amplifier circuit 518, amplify the received signal, and then provide the amplified signal to one or more storage circuits. The storage circuits can include flip-flop circuits, or a first latch circuit 530 or a second latch circuit 532. In an example, the global sense amplifier 526 includes a second amplifier circuit 528 configured to compare the received signal to a reference, and the comparison result is amplified and provided to the one or more storage circuits. The storage circuits can be activated in a time-multiplexed manner to receive information from the second amplifier circuit 528 at respective different times, such as to receive information about a most significant bit at a first time, and to receive information about a least significant bit at a subsequent second time.

In an example, the first local sense amplifier 514 and one or more other instances of a local sense amplifier can be physically located (i.e., integrated) at or adjacent to the subarrays that comprise the memory array 502. In an example, the global sense amplifier 526, such as including the latch circuits, can be physically larger than the first local sense amplifier 514 and can be physically located (i.e., integrated) outside of the array area. Other configurations can similarly be used.

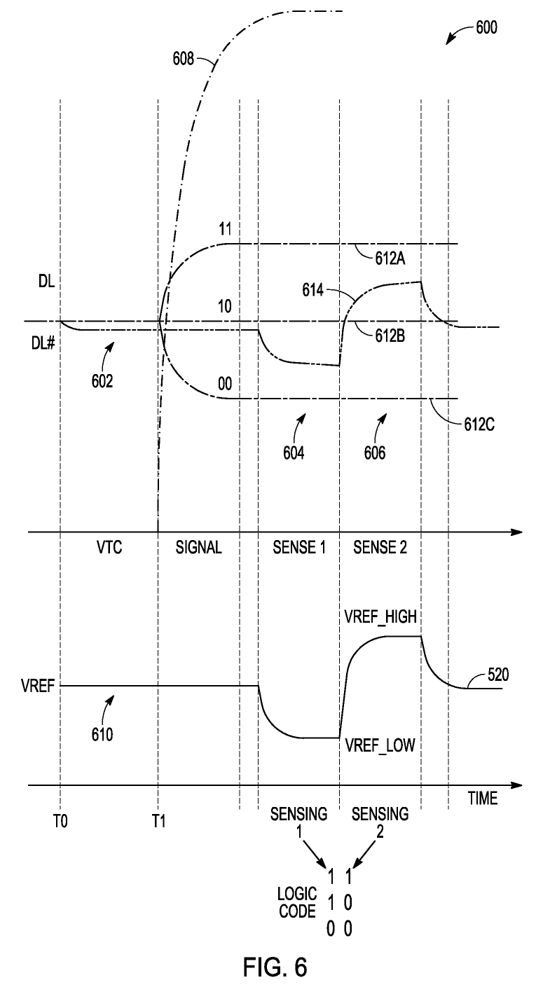

An example of a multilevel cell sensing operation can be understood with reference to FIG. 5 and FIG. 6. FIG. 6 illustrates generally an example of a sense operation timing diagram 600, such as for reading information from the first target memory cell 508 of the first memory device 500.

A sense operation can begin at time T0 with the first switch S1 closed, the second switch S2 open, and the third switch S3 closed. In this configuration, the first amplifier circuit 518 provides unity gain (e.g., due to the feedback path via the first switch S1), and the bias voltage signal provided by the bias circuit 534 (e.g., 0.5 V) is provided by the first amplifier circuit 518 at the first digit line bar 522. In an example, the first amplifier circuit 518 imparts an offset, and accordingly the bias voltage signal can be adjusted by the offset and the resulting signal can be provided at the first digit line bar 522. The inherent capacitance of the first digit line bar 522 can be used to temporarily store this initial output information from the first amplifier circuit 518. The amplifier output with offset is illustrated in the digit line bar signal 614 in the example of the sense operation timing diagram 600 at 602, following time T0. Following a settling time (or charging time), the sense operation can continue at time T1.

At time T1, the second switch S2 can be closed, and the first switch S1 and the third switch S3 can be opened. In this configuration, the first amplifier circuit 518 can receive a cell voltage signal and drive the signal line 524. The first word line 510 can then be activated, as represented by a word line activation signal 608. The cell voltage signal can have one of multiple values, as indicated by the first potential digit line signal 612a (e.g., corresponding to logic code “11”), the second potential digit line signal 612b (e.g., corresponding to logic code “10”), and the third potential digit line signal 612c (e.g., corresponding to logic code “00”).

The first local reference signal 520 can be adjusted according to a specified reference voltage pattern 610 so that a charge transfer occurs from the first local reference signal 520 source to the first digit line bar 522. In an example, a source for the first local reference signal 520 comprises a switched power supply or a three-way switch coupled to respective constant voltage sources. Other sources can similarly be used.

In an example, the reference voltage pattern 610 includes first reducing the first local reference signal 520 from an initial value (e.g., 0.5 V initial value) to a lower reference value VREF_low during a first read phase 604. Due to the in-line capacitor between the first local reference signal 520 source and the inverting input of the first amplifier circuit 518, a charge transfer occurs at the first digit line bar 522. As the first local reference signal 520 moves from VREF to VREF_low, the voltage on the first digit line bar 522 correspondingly decreases. The in-line capacitor can be sized such that the voltage on the first digit line bar 522 is between the potential distributions of voltage signals that represent logic codes “10” and “00” (see, e.g., the example of FIG. 4 at the second time 404 and the third time 406, respectively). The reference voltage pattern 610 can continue from the first read phase 604 to a second read phase 606. At the second read phase 606, the first local reference signal 520 can move from VREF_low to VREF_high, and VREF_high can be greater than VREF.

Continuing with the example of FIG. 6, the first local reference signal 520 settles sufficiently near VREF_low at the first read phase 604. During the first read phase 604, the first amplifier circuit 518 can be used to perform a comparison function, using the reference signal and the charge information from the first target memory cell 508, to determine whether the charge stored by the first target memory cell 508 represents a logic code “00” or represents another logic code (e.g., “10” or “11”). If the charge stored by the first target memory cell 508 represents a logic code “00,” then the voltage on the first digit line 512 is lower than the voltage on the first digit line bar 522. Accordingly, during the first read phase 604, when the first amplifier circuit 518 receives the cell voltage from the first digit line 512 at one input, and receives approximately VREF_low from the first digit line bar 522 at its other input, then the output of the first amplifier circuit 518 provided to the signal line 524 is low (e.g., less than 0.5 V, in this example). The second amplifier circuit 528 of the global sense amplifier 526 can receive the low signal via the signal line 524 and store the result in the first latch circuit 530 as the most significant bit, still during the first read phase 604. In an example, the second amplifier circuit 528 is a comparator circuit configured to receive the output of the first amplifier circuit 518 from the signal line 524, compare the output to a reference (e.g., 0.5 V), and then provide a signal indicating the comparison result to a selected one of multiple latch circuits.

In another example, if the charge stored by the first target memory cell 508 represents other than the logic code “00,” then the voltage on the first digit line 512 during the first read phase 604 is greater than the voltage on the first digit line bar 522. Accordingly, during the first read phase 604, the output of the first amplifier circuit 518 provided to the signal line 524 is high (e.g., greater than 0.5 V, in this example). The second amplifier circuit 528 of the global sense amplifier 526 can receive the high signal via the signal line 524 and store the result in the first latch circuit 530 as the most significant bit, still during the first read phase 604.

Following the first read phase 604, the first local reference signal 520 is adjusted from VREF_low to VREF_high during the second read phase 606. The voltage on the first digit line bar 522 is accordingly adjusted to be between the potential distributions of voltage signals that represent logic codes “10” and “11” (see, e.g., the example of FIG. 4 at the second time 404 and the first time 402, respectively). When the first local reference signal 520 settles sufficiently near VREF_high during the second read phase 606, the first amplifier circuit 518 can perform a comparison function to determine whether the charge stored by the first target memory cell 508 represents the logic code “10” or “11.”

Alternatively to the example of FIG. 6 and the particular reference voltage pattern 610 used, other reference voltage patterns can be used. For example, the first local reference signal 520 can transition from VREF to VREF_high first, during the first read phase 604, and then to VREF_low during the second read phase 606. In this example, the first latch circuit 530 filled during the first read phase 604 contains the least significant bit and the second latch circuit 532 filled during the second read phase 606 contains the most significant bit.

In an example, logic code information can be read from multiple cells using time-multiplexed sensing. The time-multiplexed sensing can include reading information from multiple cells in sequence. In an example, the multiple cells can be accessed using the same or shared word line, and can comprise cells of the same array (e.g., corresponding to the same bank, subarray, or other division of a memory cell array in a memory device). In an example, the digit lines from the cells can be coupled to respective different local sense amplifiers, and the outputs from the local sense amplifiers can be coupled to a global sense amplifier that serves the array. In an example, the global sense amplifier can be configured to sense information from cells of multiple different subarrays or other subdivisions of the memory device array.

FIG. 7 illustrates generally an example of a portion of a second memory device 700 such as can include various components of the first memory device 500. The second memory device 700 can include multiple memory cells comprising a portion of a first array. For example, the second memory device 700 can include the first target memory cell 508, a second target memory cell 716, a third target memory cell 718, and a fourth target memory cell 720. For purposes of illustration, the example of FIG. 7 shows four memory cells, however, additional or fewer cells can similarly be used.

In the example of FIG. 7, the several target memory cells are coupled to the first word line 510, and each of the cells is configured to be activated by a signal on the first word line 510. Each of the cells is coupled to a respective different digit line, and is associated with a respective different local sense amplifier and digit line bar. For example, the first target memory cell 508 is coupled to an input of the first local sense amplifier 514 via the first digit line 512, and an output of the first local sense amplifier 514 is selectively coupled with one of the first digit line bar 522 and the signal line 524. The second target memory cell 716 is coupled to an input of a second local sense amplifier 702 via a second digit line 736, and an output of the second local sense amplifier 702 is selectively coupled with one of a second digit line bar 742 and the signal line 524. The third target memory cell 718 is coupled to an input of a third local sense amplifier 704 via a third digit line 738, and an output of the third local sense amplifier 704 is selectively coupled with one of a third digit line bar 744 and the signal line 524. The fourth target memory cell 720 is coupled to an input of a fourth local sense amplifier 706 via a fourth digit line 740, and an output of the fourth local sense amplifier 706 is selectively coupled with one of a fourth digit line bar 746 and the signal line 524. Each of the local sense amplifiers can be similarly configured. That is, each local sense amplifier can represent a different instance of the same local sense amplifier topology.

In the example of FIG. 5 and FIG. 6 discussed above, a reference voltage pattern 610 is provided, and implemented using the first local sense amplifier 514, to perform various signal comparisons with stored charge information from the first target memory cell 508. According to the reference voltage pattern 610, the first local reference signal 520 is provided at multiple different levels at different times corresponding to different read phases. The same or similar pattern can be applied, in a time-multiplexed manner, to read stored charge information from the several target memory cells in the example of FIG. 7.

FIG. 7 illustrates generally an example of a reference signal timing diagram 722 showing time-varying reference voltage signals, or signal patterns, that can be implemented by a centralized reference voltage signal generator or source, or can be generated by multiple reference voltage signal sources respectively corresponding to the first local sense amplifier 514, the second local sense amplifier 702, the third local sense amplifier 704, and the fourth local sense amplifier 706. For example, the reference signal timing diagram 722 includes the first local reference signal 520, a second local reference signal 710, a third local reference signal 712, and a fourth local reference signal 714. Each of the local reference signals corresponds to multiple respective read phases that can be implemented, in sequence, using the respective local sense amplifiers.

By way of example, the charge information stored in the first target memory cell 508 can be read during the first read phase 604 and the second read phase 606 (e.g., using the first local reference signal 520 to drive the first local sense amplifier 514) to populate the first latch circuit 530 and the second latch circuit 532, respectively, as discussed above in the discussion of FIG. 6. Similarly, the charge information stored in the second target memory cell 716 can be read during a subsequent third read phase and a further subsequent fourth read phase (e.g., using the second local reference signal 710 to drive the second local sense amplifier 702) to populate a third latch circuit 724 and a fourth latch circuit 726, respectively. The charge information stored in the third target memory cell 718 can be read during a fifth read phase and a sixth read phase (e.g., using the third local reference signal 712 to drive the third local sense amplifier 704) to populate a fifth latch circuit 728 and a sixth latch circuit 730, respectively. The charge information stored in the fourth target memory cell 720 can be read during a seventh read phase and an eighth read phase (e.g., using the fourth local reference signal 714 to drive the fourth local sense amplifier 706) to populate a seventh latch circuit 732 and an eighth latch circuit 734, respectively. The various latch circuits can thus receive sequential measurements, staggered in time, from the second amplifier circuit 528 via the shared signal line 524.

In an example, a multiplexer circuit can be coupled between the global sense amplifier 526 and the signal line 524. The multiplexer circuit can couple one leg of the signal line 524 to the global sense amplifier 526 at any given time. The multiplexer circuit can help minimize capacitive loading effects at the input to the second amplifier circuit 528 by decoupling portions of the signal line 524 that are unused during a particular read phase. The multiplexer circuit can be similarly used during writeback procedures, as further discussed below.

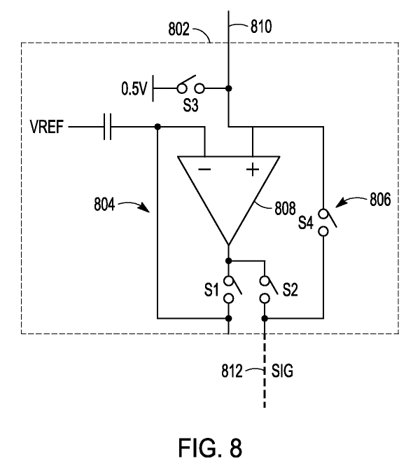

FIG. 8 illustrates generally an example of a fifth local sense amplifier 802 with a writeback shunt circuit. The fifth local sense amplifier 802 can include an example of any one or more of the other local sense amplifiers discussed herein. The fifth local sense amplifier 802 includes an amplifier circuit 808, a feedback circuit 804, and a writeback circuit 806. The amplifier circuit 808 can be configured similarly to the example of the first amplifier circuit 518. For example, the amplifier circuit 808 can be coupled to a digit line 810 and configured to receive an input signal, such as representing a cell voltage, at a first amplifier input. The feedback circuit 804 can be used to selectively couple the output of the amplifier circuit 808 to its non-inverting input using a first switch S1. The fifth local sense amplifier 802 includes a second switch S2 that selectively couples the output of the amplifier circuit 808 to a signal line 812. In an example, the signal line 812 can be coupled to a global sense amplifier, similarly to the example of the signal line 524 that is coupled to the global sense amplifier 526 in FIG. 5. The fifth local sense amplifier 802 includes a third switch S3 that selectively couples a non-inverting input of the fifth local sense amplifier 802 to a bias source.

After a sense operation is completed to read data from a particular memory cell, data or charge generally needs to be restored to the same particular memory cell. A writeback procedure is used to charge the memory cell. The example of the fifth local sense amplifier 802 includes a writeback circuit 806 that is used in a writeback process. In the example of the fifth local sense amplifier 802, the writeback circuit 806 includes a fourth switch S4 that selectively couples the signal line 812 to the digit line 810. That is, a signal or charge on the signal line 812 is selectively used to provide a signal to the particular memory cell that is coupled to the digit line 810.

The writeback process can be performed in coordination with, or after, bit information about a particular memory cell is written to a latch circuit by a global sense amplifier. In an example, during a sense operation, the second switch S2 is closed and the signal line 812 can provide cell voltage information to the global sense amplifier 526. In response, the global sense amplifier 526 can provide a signal to a latch circuit (e.g., to the first latch circuit 530 or the second latch circuit 532, depending on the read phase). Next, the second switch S2 can open and, while maintaining S1 in an open state, the fourth switch S4 can close to couple the signal line 812 to the digit line 810. If the word line for the particular memory cell is still active when the fourth switch S4 is closed, then the charge on the signal line 812 can be transferred to, and stored by, the particular memory cell. After a specified writeback time elapses that is sufficient to charge the charge storage element for the particular memory cell, the fourth switch S4 of the fifth local sense amplifier 802 can open and a new read phase, or a writeback phase for another cell, can begin.

Referring again to the example of FIG. 7, assume that each of the local sense amplifier instances includes a respective fourth switch S4, designated S4_0 for the first local sense amplifier 514, S4_1 for the second local sense amplifier 702, S4_2 for the third local sense amplifier 704, and S4_3 for the fourth local sense amplifier 706. The fourth switch instances can be sequentially and successively closed (e.g., in coordination with a multiplexer circuit at the latch circuits of the global sense amplifier 526) to allow signals from the corresponding latch circuits to charge the signal line 524 and a particular one of the digit lines.

In an example, a read and writeback procedure can proceed as follows. During a sequence of read events for the first target memory cell 508 through the fourth target memory cell 720, the fourth switches S4_0 through S4_3 are open, and the global sense amplifier 526 populates the first latch circuit 530 through the eighth latch circuit 734, for example, using the operations discussed herein with reference to FIG. 7. After the eighth latch circuit 734 is populated, a multiple-phase writeback procedure can begin to recharge each of the first target memory cell 508 through the fourth target memory cell 720.

The first target memory cell 508 can be recharged during a first writeback phase. In the first writeback phase, at the first local sense amplifier 514, the fourth switch S4_0 can be closed, while the first and second switches S1 and S2 of the first local sense amplifier 514 are held open. The first and second switches S1 and S2 at each of the second local sense amplifier 702, the third local sense amplifier 704, and the fourth local sense amplifier 706 can be held open during the first writeback phase, and the fourth switches S4_1, S4_2, and S4_3 can be held open during the first writeback phase. Accordingly, the signal line 524 can be coupled to the first digit line 512 and charge received from the corresponding latch circuits (e.g., the first latch circuit 530 and the second latch circuit 532) can be transferred to the first target memory cell 508.

A second writeback phase can follow the first writeback phase, immediately or after a specified settling delay. The second target memory cell 716 can be recharged during the second writeback phase. In the second writeback phase, at the second local sense amplifier 702, the fourth switch S4_1 can be closed, while the first and second switches S1 and S2 of the second local sense amplifier 702 are held open. The first and second switches S1 and S2 at each of the first local sense amplifier 514, the third local sense amplifier 704, and the fourth local sense amplifier 706 can be held open during the second writeback phase, and the fourth switches S4_0, S4_2, and S4_3 can be held open during the second writeback phase. Accordingly, the signal line 524 can be coupled to the second digit line 736 and charge received from the corresponding latch circuits (e.g., the third latch circuit 724 and the fourth latch circuit 726) can be transferred to the second target memory cell 716. Third and fourth writeback phases can be similarly provided to recharge the third target memory cell 718 and the fourth target memory cell 720, respectively.

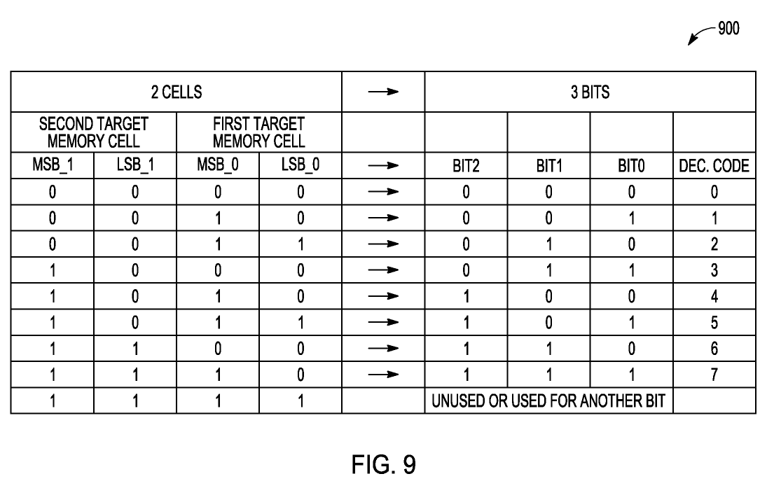

FIG. 9 illustrates generally an example of a table 900 that shows how signals stored using two multilevel memory cells can be decoded to provide more than 3 bits of information. In an example, each of the multilevel memory cells can be configured to store a charge having one of at least three different charge levels. At left, the table 900 illustrates potential values corresponding to information stored by first and second memory cells. In an example, the table 900 shows potential values corresponding to information in the first target memory cell 508 and stored by the first latch circuit 530 and the second latch circuit 532 (e.g., as MSB_0 and LSB_0, respectively), and potential values corresponding to information from the second target memory cell 716 and stored using the third latch circuit 724 and the fourth latch circuit 726 (e.g., as MSB_1 and LSB_1, respectively). As shown at left in the table 900, there are nine unique combinations available from the potential values, or “digits,” stored in the four latch circuits.

At right, the table 900 illustrates how the nine unique combinations of information in the latch circuits can be translated or decoded into 3 bits of information, or a 3-bit word. Eight combinations fully define each of the potential 3-bit words, as represented by the eight rows of the table 900. The ninth combination can be unused or can be used elsewhere, as described herein. In an example, the remaining or ninth combination can be used as a portion of another bit or another word.

Given N available memory cells, and each of the cells is configured to store multilevel (e.g., 3-level) signal information as discussed herein, the total number of bits that can be realized is given by

Number of bits = INT(log₂(3^{N}))

where INT is a function that rounds the result down to the nearest integer. It can be shown that the theoretical utilization limit is about 1.585 bits per cell, using the systems and methods discussed herein. By way of example, 12 memory cells can thus be used together to provide 19 bits of information, representing 99.90% utilization of the available combinations, and providing 7 more bits of information than would otherwise be available from 12 non-multilevel memory cells. It can be shown that multiples of 12 memory cells (e.g., 24 cells, 36 cells, etc.) provides the same 99.90% utilization. Some combinations of multiple cells realize higher utilization, for example, using 53 cells together yields 84 bits of information and represents 99.99% utilization of the available combinations, while providing 31 more bits of information than would otherwise be available from 53 non-multilevel memory cells.

Various combinatory logic, or other processor or processing circuitry, can be provided to receive information from the latch circuits and decode the received information into one or more multi-bit words. For example, the combinatory logic can be configured to receive two-digit representations of stored voltage values from latch circuits corresponding to N respective memory cells in a memory array. In an example, such as illustrated in FIG. 5 or FIG. 7, two latch circuits correspond to each memory cell: a first latch circuit is configured to store information about a most significant bit (MSB) and a second latch circuit is configured to store information about a least significant bit (LSB) corresponding to the charge stored in the memory cell. Each of the memory cells, such as can comprise any of the target memory cells discussed herein, can be configured to store a charge having one of at least three different charge levels. Based on the received two-digit representations of the stored voltage values, the combinatory logic can provide an M-bit word, wherein M is the nearest and least integer to a result of the function log₂(3^{N}).

The combinatory logic can be configured to process the two-digit representations from N memory cells to provide one of 2^{M} unique codes or words. Referring again to the table 900, for example, the combinatory logic can be configured to receive the first row of latch circuit information (e.g., corresponding to digits “0000”) and, in response, provide a first 3-bit word (e.g., “000”), or to receive the second row of latch circuit information (e.g., corresponding to digits “0010”) and, in response, provide a second 3-bit word (e.g., “001”), and so on. In other words, the combinatory logic can receive information corresponding to the charges stored by multiple different cells, process the charge information together, and provide a multi-bit result.

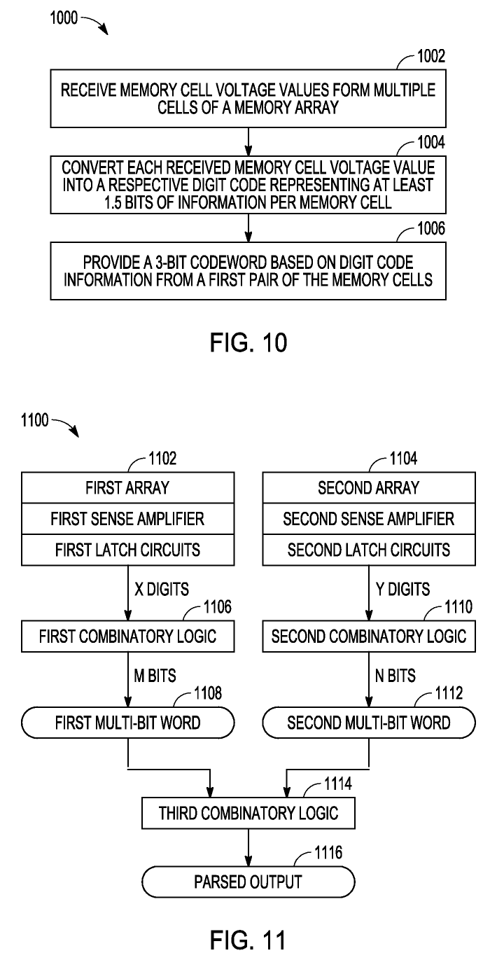

FIG. 10 illustrates generally an example of a first method 1000 for providing a 3-bit codeword based on information from a pair of multilevel memory cells. At operation 1002, the first method 1000 includes receiving memory cell voltage values from multiple cells of a memory array. The operation 1002 can include receiving the cell voltage values from each of multiple cells, and each cell is configured to store a charge having one of at least three different charge levels.

In an example, each of the multiple cells of the memory array corresponds to a respective digit line. At operation 1002, receiving the memory cell voltage values can include receiving the voltage values at respective local sense amplifiers coupled to the respective digit lines.

At operation 1004, the first method 1000 includes converting each received memory cell voltage value into a respective digit code representing at least 1.5 bits of information per memory cell. In an example, converting each received memory cell voltage value into a respective digit code at operation 1004 includes, for a first memory cell of the multiple cells, receiving a first portion of a voltage reference signal at a first input of a first local sense amplifier, and receiving a first memory cell voltage signal from the first memory cell at a second input of the first local sense amplifier. The operation 1004 can further include, at an output of the first local sense amplifier, providing a first comparison result that indicates a relationship between the first portion of the voltage reference signal and the memory cell voltage signal. In an example, operation 1004 includes storing a first digit code, at a first latch circuit, and the first digit code is based on the first comparison result.

In an example, operation 1004 can include receiving a second portion of the voltage reference signal at the first input of the first local sense amplifier and, at the output of the first local sense amplifier, providing a second comparison result that indicates a relationship between the second portion of the voltage reference signal and the memory cell voltage signal. The operation 1004 can further include storing a second digit code, at a second latch circuit, and the second digit code is based on the second comparison result.

In an example, operation 1004 can include receiving, at a global sense amplifier and at respective different times, the first and second comparison results from the first local sense amplifier and, in response, providing the first and second digit codes to the first and second latch circuits, respectively. A multiplexer circuit can be used to coordinate coupling the global sense amplifier to the respective latch circuits at appropriate times during the sensing or cell reading cycle.

In an example, after operation 1004 and optionally before operation 1006, the first method 1000 can include writing back information to the first memory cell. The written back information can correspond to the first memory cell voltage signal. In an example, writing back the information to the first memory cell includes using a shunt circuit to bypass the first local sense amplifier.

At operation 1006, the first method 1000 includes providing a 3-bit codeword based on digit code information from a first pair of the memory cells. In an example, providing the 3-bit codeword includes using a combinatory logic circuit to receive the digit code information and, in response, providing a corresponding codeword.

FIG. 11 illustrates generally an example of a processing system 1100 that includes combinatory logic (i.e., circuitry) configured to provide one or more multi-bit words based on data stored in latch circuits of a memory device. The processing system 1100 includes first latch circuits 1102 and different second latch circuits 1104 configured to store information from memory cells of respective first and second memory cell arrays. The first latch circuits 1102 and second latch circuits 1104 can each comprise the same number of latch circuits or can comprise different numbers of latch circuits.

In an example, the first and second memory cell arrays correspond to the first memory array 130 and/or the second memory array 136 of the same memory device, or correspond to arrays of respective different memory devices. In an example, the first latch circuits 1102 are populated using a first global sense amplifier and the second latch circuits 1104 are populated using a different second global sense amplifier. In another example, the first latch circuits 1102 and the second latch circuits 1104 can be populated in a time-multiplexed manner using the same global sense amplifier.

The processing system 1100 includes first combinatory logic 1106 configured to receive X digits (where X is an integer number of digits or units of information) from the first latch circuits 1102 and, in response, provide a first multi-bit word 1108, such as an M-bit word (where M is an integer number of bits). The processing system 1100 can include second combinatory logic 1110 configured to receive Y digits (where Y is an integer number of digits or units of information) from the second latch circuits 1104 and, in response, provide a second multi-bit word 1112, such as an N-bit word (where N is an integer number of bits). The number of digits processed by the first combinatory logic 1106 and the second combinatory logic 1110 can be the same or different. Accordingly, the number of bits that comprise the first multi-bit word 1108 and the second multi-bit word 1112 can be the same or different.

In an example, the first combinatory logic 1106 and/or the second combinatory logic 1110 comprises one or more of a processor circuit, discrete logic circuitry (e.g., comprising a series of gates), and a lookup table. In an example, a processor circuit can be programmed to perform complex logic operations. It can execute algorithms that interpret the charge levels in the memory cells as specific binary values. The flexibility of a processor circuit allows for sophisticated error correction and data management techniques, which can be useful in high-density memory configurations. In an example, discrete logic circuitry includes individual logic gates arranged to perform specific functions. Discrete logic circuits can be faster than processor circuits due to their simplicity and the absence of an instruction execution cycle. The discrete logic circuits can be hardwired to perform a set of predetermined logic functions that output a multi-bit word. In an example, a lookup table that includes a precomputed array of values can be used (see, e.g., the example of the table 900). A lookup table provides a quick and efficient way to determine the output for a given input by direct indexing rather than computation. In an example, a lookup table can be used to translate the various charge levels in the memory cells into corresponding binary values and multi-bit words. Using a lookup table can be fast and may consume less power than a processor-implemented, algorithmic technique.

In an example, the first multi-bit word 1108 and/or the second multi-bit word 1112 can be provided to a memory controller for further operations. For example, the multi-bit word(s) can be provided to a memory device memory controller (e.g., the device memory controller 124) or can be transmitted to a host device, such as for further processing by a host memory controller or host processor (e.g., the external memory controller 116 or the processor 118 at the host device 102).

In an example, a second stage or other combinatory logic can be provided to parse one or more multi-bit words into bytes or other bit groups that can be further processed by a memory device. The example of the processing system 1100 includes third combinatory logic 1114 that can receive one or both of the first multi-bit word 1108 and the second multi-bit word 1112 and, in response, provide a parsed output 1116.

In an example, the first multi-bit word 1108 is an M-bit word, and the second multi-bit word 1112 is a N-bit word, where M and N are integers greater than 1. Each of the words can correspond to groups of memory cells that have the same number of cells or a different number of cells. Further combinatory logic, such as third combinatory logic 1114 in the example of the processing system 1100, can be configured to receive the first multi-bit word 1108 and the second multi-bit word 1112 and, in response, provide corresponding bytes of information to, e.g., a memory controller, such as the local memory controller 128 or the external memory controller 116 from the example system 100 of FIG. 1.

In an example, the parsed output 1116 from the third combinatory logic 1114 is structured to facilitate organization and manipulation of data within the processing system 1100. The parsed output 1116 can be formatted into bytes or other predefined bit groupings suitable for interfacing with subsequent stages of data processing or storage. The third combinatory logic 1114 can be an intermediary that translates the first multi-bit word 1108 and/or the second multi-bit word 1112 into a more useful data format, thereby enhancing compatibility with a wide range of memory controllers and processors.

In an example, the processing system 1100 comprises control logic that orchestrates the operation of the first and second groups of latch circuits and the combinatory logic. The control logic can, for example, coordinating the timing, sequencing, and execution of data retrieval, processing, and output tasks. It ensures that the correct data is accessed and processed in accordance with the operational protocols of the processing system 1100 or a memory system such as the example system 100.

In an embodiment, the processing system 1100 includes an error correction module. The error correction module can be configured to identify and correct errors that may occur during the storage, retrieval, or transmission of data. The error correction module helps enhances the reliability and integrity of the data managed by the processing system 1100.

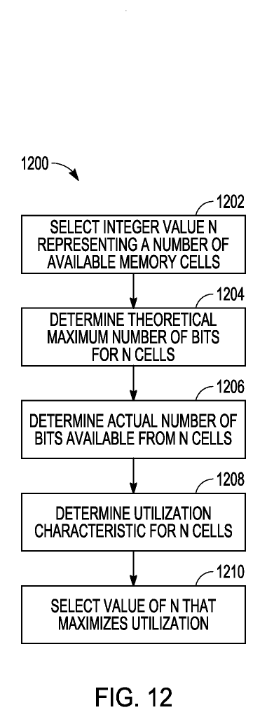

FIG. 12 illustrates generally an example of a memory cell usage optimization method 1200 that includes selecting a particular number of memory cells to use together to provide a multiple-bit word. At operation 1202, the method includes selecting an integer value N that represents a number of available memory cells. The available memory cells can be cells that can be accessed and read together by one or more instances of combinatory logic that can provide a multi-bit word result.

At operation 1204, the method includes determining a theoretical maximum number of bits that can be realized using the N cells. In an example, the N cells include cells that can each store a multi-valued level or charge. For example, each cell can store at least three discrete voltage levels or charges. In an example, each cell is configured to store more than one bit and less than two bits of information.

At operation 1206, the method includes determining an actual number of bits that can be realized using the N memory cells. In an example, operation 1206 includes determining a nearest and least integer to a result of the function log₂(3^{N}), which integer can represent a maximum number of bits that can be realized for N memory cells, where each of the N memory cells is configured to store at least three discrete voltage levels or charges.

At operation 1208, the method includes determining a utilization characteristic for the N cells. The utilization characteristic can be based on a relationship between the actual number of bits available and the theoretical maximum number of bits that can be stored. Upon evaluating the utilization characteristics for each of multiple values of N, the method can include, at operation 1210, selecting a value of N that maximizes the utilization characteristic. If the process of evaluating different values of N is complete, then the method ends. If further values of N are to be considered, then the method loops back to select a new integer value of N at operation 1202.

Electronic devices, such as mobile electronic devices (e.g., smart phones, tablets, etc.), electronic devices for use in automotive applications (e.g., automotive sensors, control units, driver assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or nonvolatile memory device, such as DRAM, mobile or low-power double-data-rate synchronous DRAM (DDR SDRAM), etc.); and a storage device (e.g., non-volatile memory (NVM) device, such as flash memory (e.g., 3D NAND flash), ROM, a solid-state drive (SSD), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

To better illustrate the multilevel memory devices and device management systems discussed herein, a non-limiting set of Example embodiments are set forth below as numerically identified Examples.

Example 1 is a memory device comprising: an array of memory cells including at least first and second memory cells; a first amplifier circuit (e.g., a local sense amplifier) configured to provide, at a first amplifier output node and during a first read phase, a first comparison result (e.g., a first “digit”) based on a first cell voltage signal of the first memory cell and a first voltage reference signal (e.g., Vref_low), and to provide, during a second read phase, a second comparison result (e.g., a second “digit”) based on the first cell voltage signal and a second voltage reference signal (e.g., Vref_high); and first and second latch circuits configured to store information about the first and second comparison results, respectively.

In Example 2, the subject matter of Example 1 optionally includes a second amplifier circuit, wherein the second amplifier circuit includes a first input coupled to the first amplifier output node and the second amplifier circuit includes an output coupled to a selected one of the first and second latch circuits.

In Example 3, the subject matter of Example 2 optionally includes the second amplifier circuit is a comparator, and the second amplifier circuit includes a second input configured to receive a third voltage reference signal (e.g., 0.5V) from a reference signal source.

In Example 4, the subject matter of any one or more of Examples 1–3 optionally includes the first amplifier circuit including: a first input node coupled to a digit line (DL) of the array; and a first output node selectively coupled to one of a complement digit line (DL#) and an input of a second amplifier circuit.

In Example 5, the subject matter of Example 4 optionally includes the first amplifier circuit includes a second input node coupled to the complement digit line (DL#) and a reference signal source.

Example 6 is a method comprising: receiving memory cell voltage values from multiple cells of a memory array, wherein each of the cells is configured to store a charge having one of at least three different charge levels; converting each received memory cell voltage value into a respective digit code representing more than 1 bit per memory cell; and based on digit code information from a first pair of the memory cells, providing a multiple-bit codeword.

In Example 7, the subject matter of Example 6 optionally includes converting each received memory cell voltage value into a respective digit code including converting each received memory cell voltage into a respective digit code representing at least 1.5 bits of information per memory cell; and based on the digit code information from the first pair of the memory cells, providing a three-bit codeword.

In Example 8, the subject matter of any one or more of Examples 6–7 optionally includes or uses each of the multiple cells of the memory array corresponding to a respective digit line, and wherein receiving the memory cell voltage values includes receiving the voltage values at respective local sense amplifiers coupled to the respective digit lines.

In Example 9, the subject matter of Example 8 optionally includes converting each received memory cell voltage value into a respective digit code including, for a first memory cell of the multiple cells: receiving a first portion of a voltage reference signal at a first input of a first local sense amplifier of the local sense amplifiers; receiving a first memory cell voltage signal from the first memory cell at a second input of the first local sense amplifier; at an output of the first local sense amplifier, providing a first comparison result that indicates a relationship between the first portion of the voltage reference signal and the memory cell voltage signal; and storing a first digit code, at a first latch circuit, wherein the first digit code is based on the first comparison result.

In Example 10, the subject matter of Example 9 optionally includes receiving a second portion of the voltage reference signal at the first input of the first local sense amplifier. In an example, Example 10 can include, at the output of the first local sense amplifier, providing a second comparison result that indicates a relationship between the second portion of the voltage reference signal and the memory cell voltage signal; and storing a second digit code, at a second latch circuit, wherein the second digit code is based on the second comparison result.

In Example 11, the subject matter of Example 10 optionally includes receiving, at a global sense amplifier and at respective different times, the first and second comparison results from the first local sense amplifier and, in response, providing the first and second digit codes to the first and second latch circuits, respectively.

In Example 12, the subject matter of Example 11 optionally includes providing the first and second digit codes to the first and second latch circuits using the global sense amplifier to compare the first and second comparison results with a second reference signal.

In Example 13, the subject matter of any one or more of Examples 10–12 optionally includes writing back information to the first memory cell, wherein the written back information corresponds to the first memory cell voltage signal.

In Example 14, the subject matter of Example 13 optionally includes writing back the information to the first memory cell using a shunt circuit to bypass the first local sense amplifier.

In Example 15, the subject matter of any one or more of Examples 6–14 optionally includes providing the multiple-bit codeword using a combinatory logic circuit to receive the digit code information and, in response, provide a corresponding codeword.

Example 16 is a method comprising: receiving a first memory cell voltage value from a first memory cell of a memory cell array; receiving a second memory cell voltage value from a second memory cell of the memory cell array; converting the first memory cell voltage value to a first two-digit representation, wherein the first two-digit representation corresponds to less than two bits of information; converting the second memory cell voltage value to a second two-digit representation, wherein the second two-digit representation corresponds to less than two bits of information; and based on the first and second two-digit representations, providing a three-bit codeword.

In Example 17, the subject matter of Example 16 optionally includes converting the first memory cell voltage value to a first two-digit representation includes using a first local sense amplifier and a first global sense amplifier; and wherein converting the second memory cell voltage value to a second two-digit representation includes using a second local sense amplifier and the same first global sense amplifier.

In Example 18, the subject matter of Example 17 optionally includes shunting the first local sense amplifier and writing back the first memory cell voltage value to the first memory cell at a first time, and shunting the second local sense amplifier and writing back the sense memory cell voltage value to the second memory cell at a subsequent second time.

In Example 19, the subject matter of any one or more of Examples 16–18 optionally includes providing the three-bit codeword, including receiving the first and second two-digit representations at first combinatory logic and, in response, providing the three-bit codeword.

In Example 20, the subject matter of any one or more of Examples 16–19 optionally includes converting the first memory cell voltage value to a first two-digit representation including comparing, during a first read phase, the first memory cell voltage value to a first portion of a time-varying voltage reference signal, and comparing, during a second read phase, the first memory cell voltage value to a second portion of the time-varying voltage reference signal, wherein the first and second portions of the time-varying voltage reference signal are differently valued.

Example 21 is a memory device comprising: first combinatory logic configured to: receive multiple-digit representations of stored voltage values from each of N respective memory cells in a first memory array, wherein each of the memory cells is configured to store a charge having one of at least three different charge levels; and based on the received multiple-digit representations of the stored voltage values, provide a first multiple-bit word, wherein a number of bits in the first multiple-bit word is greater than N.

In Example 22, the subject matter of Example 21 optionally includes the first memory array and a first sense amplifier, wherein the first sense amplifier is configured to provide, at a first amplifier output node and during a first read phase, a first digit based on a first cell voltage signal of a first memory cell and a first voltage reference signal, and to provide, during a second read phase, a second digit based on the first cell voltage signal and a second voltage reference signal.

In Example 23, the subject matter of any one or more of Examples 21–22 optionally includes second combinatory logic configured to: receive multiple-digit representations of stored voltage values from each of M respective memory cells in a second memory array, wherein each of the memory cells is configured to store a charge having one of at least three different charge levels; and based on the received multiple-digit representations of the stored voltage values, provide a second multiple-bit word, wherein a number of bits in the second multiple-bit word is greater than M.

In Example 24, the subject matter of Example 23 optionally includes the number of bits in the first multiple-bit word is different than the number of bits in the second multiple-bit word.

In Example 25, the subject matter of Example 24 optionally includes the number of bits in the first multiple-bit word is the nearest and least integer to a result of the function log₂(3^N), and the number of bits in the second multiple-bit word is the nearest and least integer to a result of the function log₂(3^M).

In Example 26, the subject matter of any one or more of Examples 23–25 optionally includes third combinatory logic configured to provide a multiple-byte output based on the first multiple-bit word from the first combinatory logic and the second multiple-bit word from the second combinatory logic.

In Example 27, the subject matter of any one or more of Examples 23–26 optionally includes the first memory array, the second memory array, a first sense amplifier, and a second sense amplifier. In Example 27, the first sense amplifier is configured to provide, at a first amplifier output node and during a first read phase, a first digit based on a first cell voltage signal of a first memory cell and a first voltage reference signal, and to provide, during a second read phase, a second digit based on the first cell voltage signal and a second voltage reference signal. In Example 27, the second sense amplifier is configured to provide, at a second amplifier output node and during the first read phase, a third digit based on a second cell voltage signal of a second memory cell and the first voltage reference signal, and to provide, during the second read phase, a fourth digit based on the second cell voltage signal and the second voltage reference signal.

In Example 28, the subject matter of any one or more of Examples 23–27 optionally includes the first memory array, the second memory array, a first sense amplifier, and a second sense amplifier; wherein the first sense amplifier is configured to provide, at a first amplifier output node and during a first read phase, a first digit based on a first cell voltage signal of a first memory cell and a first voltage reference signal, and to provide, during a second read phase, a second digit based on the first cell voltage signal and a second voltage reference signal; and wherein the second sense amplifier is configured to provide, at a second amplifier output node and during a third read phase, a third digit based on a second cell voltage signal of a second memory cell and the first voltage reference signal, and to provide, during a fourth read phase, a fourth digit based on the second cell voltage signal and the second voltage reference signal, wherein the second read phase follows the first read phase, the third read phase follows the second read phase, and the fourth read phase follows the third read phase.

Example 29 is a memory device comprising: first combinatory logic configured to: receive two-digit representations of stored voltage values from N respective memory cells in a memory array, wherein each of the memory cells is configured to store a charge having one of at least three different charge levels; and based on the received two-digit representations of the stored voltage values, provide an M-bit word, wherein M is the nearest and least integer to a result of the function log₂(3^N).

In Example 30, the subject matter of Example 29 optionally includes the first combinatory logic is configured to process together the two-digit representations from N memory cells to provide one of 2^M unique codes.

In Example 31, the subject matter of Example 30 optionally includes, for each of multiple instances of the first combinatory logic, N is an integer that maximizes a ratio of an actual number of bits available from the N memory cells to a theoretical maximum number of bits that can be stored for the N cells.

In Example 32, the subject matter of Example 31 optionally includes the actual number of bits available from the N memory cells is M, and a theoretical maximum number of bits that can be stored for the N cells is log₂(3^N).

In Example 33, the subject matter of any one or more of Examples 29–32 optionally includes second combinatory logic configured to provide an L-bit word; and subsequent combinatory logic configured to receive the M-bit word from the first combinatory logic and to receive the L-bit word from the second combinatory logic and, in response, provide multiple bytes of information to a memory controller of the memory device.

In Example 34, the subject matter of Example 33 optionally includes a first sense amplifier and a second sense amplifier, wherein the first sense amplifier is configured to provide the voltage values used to provide the M-bit word, and the second sense amplifier is configured to provide other voltage values used to provide the L-bit word.

Example 35 is a method for selecting a number of memory cells to use together to provide a multiple-bit word, the method comprising: for each of multiple integer values of N: determining a theoretical maximum number of bits that can be stored using N memory cells, wherein each of the memory cells is configured to store more than one bit and less than two bits of information; determining an actual number of bits available from the N memory cells; and determining an utilization characteristic of using the N memory cells based on a relationship between the actual number of bits available from the N memory cells and the theoretical maximum number of bits that can be stored using the N memory cells; and selecting a value of N that maximizes the utilization characteristic.

In Example 36, the subject matter of Example 35 optionally includes the multiple-bit word is an M-bit word, and M is the nearest and least integer to a result of the function log₂(3^{N}).

In Example 37, the subject matter of any one or more of Examples 35–36 optionally includes selecting a value of N that provides a utilization characteristic of at least 84%.

In Example 38, the subject matter of Example 37 optionally includes selecting a value of N that provides a utilization characteristic of at least 94%.

In Example 39, the subject matter of Example 38 optionally includes selecting a value of N that provides a utilization characteristic of at least 99%.

In Example 40, the subject matter of any one or more of Examples 35–39 optionally includes selecting the value of N that maximizes the utilization characteristic includes: determining a first utilization characteristic of using X-1 memory cells based on a relationship between the actual number of bits available from the X-1 memory cells and the theoretical maximum number of bits that can be stored using the X-1 memory cells; determining a second utilization characteristic of using X memory cells based on a relationship between the actual number of bits available from the X memory cells and the theoretical maximum number of bits that can be stored using the X memory cells; and when the first utilization characteristic exceeds the second utilization characteristic, selecting N as equal to X-1, otherwise selecting N as equal to X, wherein X is an integer greater than two.

Example 41 is at least one non-transitory, machine-readable medium including instructions that, when executed by processing circuitry, cause the processing circuitry to perform operations to implement of any of any one or more of the combinatory logic or other processing examples discussed above.

Example 42 is an apparatus comprising means to implement of any of any one or more of Examples 1–40.

Example 43 is a system to implement of any of any one or more of Examples 1–40.

Each of these non-limiting examples can stand on its own or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device comprising:
an array of memory cells including at least first and second memory cells;
a first amplifier circuit configured to provide, at a first amplifier output node and during a first read phase, a first comparison result based on a first cell voltage signal of the first memory cell and a first voltage reference signal, and to provide, during a second read phase, a second comparison result based on the first cell voltage signal and a second voltage reference signal; and
first and second latch circuits configured to store information about the first and second comparison results, respectively.

2. The memory device of claim 1, comprising a second amplifier circuit, wherein the second amplifier circuit includes a first input coupled to the first amplifier output node and the second amplifier circuit includes an output coupled to a selected one of the first and second latch circuits.

3. The memory device of claim 2, wherein the second amplifier circuit is a comparator, and wherein the second amplifier circuit includes a second input configured to receive a third voltage reference signal from a reference signal source.

4. The memory device of claim 1, wherein the first amplifier circuit includes:
a first input node coupled to a digit line (DL) of the array; and
a first output node selectively coupled to one of a complement digit line (DL#) and an input of a second amplifier circuit.

5. The memory device of claim 4, wherein the first amplifier circuit includes a second input node coupled to the complement digit line (DL#) and a reference signal source.

6. A method comprising:
receiving memory cell voltage values from multiple cells of a memory array, wherein each of the cells is configured to store a charge having one of at least three different charge levels;
converting each received memory cell voltage value into a respective digit code representing more than 1 bit per memory cell; and
based on digit code information from a first pair of the memory cells, providing a multiple-bit codeword.

7. The method of claim 6, wherein converting each received memory cell voltage value into a respective digit code includes converting each received memory cell voltage into a respective digit code representing at least 1.5 bits of information per memory cell; and based on the digit code information from the first pair of the memory cells, providing a three-bit codeword.

8. The method of claim 6, wherein each of the multiple cells of the memory array corresponds to a respective digit line, and wherein receiving the memory cell voltage values includes receiving the voltage values at respective local sense amplifiers coupled to the respective digit lines.

9. The method of claim 8, wherein converting each received memory cell voltage value into a respective digit code includes, for a first memory cell of the multiple cells:
receiving a first portion of a voltage reference signal at a first input of a first local sense amplifier of the local sense amplifiers;
receiving a first memory cell voltage signal from the first memory cell at a second input of the first local sense amplifier;
at an output of the first local sense amplifier, providing a first comparison result that indicates a relationship between the first portion of the voltage reference signal and the memory cell voltage signal; and
storing a first digit code, at a first latch circuit, wherein the first digit code is based on the first comparison result.

10. The method of claim 9, comprising:
receiving a second portion of the voltage reference signal at the first input of the first local sense amplifier;
at the output of the first local sense amplifier, providing a second comparison result that indicates a relationship between the second portion of the voltage reference signal and the memory cell voltage signal; and
storing a second digit code, at a second latch circuit, wherein the second digit code is based on the second comparison result.

11. The method of claim 10, comprising receiving, at a global sense amplifier and at respective different times, the first and second comparison results from the first local sense amplifier and, in response, providing the first and second digit codes to the first and second latch circuits, respectively.

12. The method of claim 11, wherein providing the first and second digit codes to the first and second latch circuits includes using the global sense amplifier to compare the first and second comparison results with a second reference signal.

13. The method of claim 10, comprising writing back information to the first memory cell, wherein the written back information corresponds to the first memory cell voltage signal.

14. The method of claim 13, wherein writing back the information to the first memory cell includes using a shunt circuit to bypass the first local sense amplifier.

15. The method of claim 6, wherein providing the multiple-bit codeword includes using a combinatory logic circuit to receive the digit code information and, in response, provide a corresponding codeword.

16. A method comprising:
receiving a first memory cell voltage value from a first memory cell of a memory cell array;
receiving a second memory cell voltage value from a second memory cell of the memory cell array;
converting the first memory cell voltage value to a first two-digit representation, wherein the first two-digit representation corresponds to less than two bits of information;
converting the second memory cell voltage value to a second two-digit representation, wherein the second two-digit representation corresponds to less than two bits of information; and
based on the first and second two-digit representations, providing a three-bit codeword.

17. The method of claim 16, wherein converting the first memory cell voltage value to a first two-digit representation includes using a first local sense amplifier and a first global sense amplifier; and
wherein converting the second memory cell voltage value to a second two-digit representation includes using a second local sense amplifier and the same first global sense amplifier.

18. The method of claim 17, comprising shunting the first local sense amplifier and writing back the first memory cell voltage value to the first memory cell at a first time, and shunting the second local sense amplifier and writing back the sense memory cell voltage value to the second memory cell at a subsequent second time.

19. The method of claim 16, wherein providing the three-bit codeword includes receiving the first and second two-digit representations at first combinatory logic and, in response, providing the three-bit codeword.

20. The method of claim 16, wherein converting the first memory cell voltage value to a first two-digit representation includes comparing, during a first read phase, the first memory cell voltage value to a first portion of a time-varying voltage reference signal, and comparing, during a second read phase, the first memory cell voltage value to a second portion of the time-varying voltage reference signal, wherein the first and second portions of the time-varying voltage reference signal are differently valued.
